(19) United States
(12) Patent Application Publication
(10) Pub. No.: US 2021/0225653 A1
(43) Pub. Date: Jul. 22, 2021

(54) LASER ANNEALING METHOD, LASER ANNEALING APPARATUS AND METHOD FOR PRODUCING ACTIVE MATRIX SUBSTRATE

(71) Applicant: SAKAI DISPLAY PRODUCTS CORPORATION, Sakai-shi, Osaka (JP)

(72) Inventor: SHIGERU ISHIDA, Sakai-shi, Osaka (JP)

(21) Appl. No.: 15/734,070

(22) PCT Filed: Jun. 6, 2018
(86) PCT No.: PCT/JP2018/021728

§ 371 Date: Dec. 1, 2020

(51) Int. Cl. H01L 21/268; H01L 29/66

(52) U.S. Cl. CPC H01L 21/268; H01L 29/6675

(57) ABSTRACT

A laser annealing method according to an embodiment of the present invention includes: a step of disposing substrate (1S) on a stage (70), the substrate having an amorphous silicon film formed on a surface thereof; a step of supplying a nitrogen gas at −100° C. or below toward a surface in a selected region of the amorphous silicon film; and a step of emitting a plurality of laser beams (LB) toward the selected region having the nitrogen gas supplied thereto, to form a plurality of crystalline silicon islets in the amorphous silicon film.

### TECHNICAL FIELD

The present invention relates to a laser annealing method, a laser annealing apparatus, and a method of producing an active matrix substrate that is suitable for use in the manufacture of a semiconductor device including a thin film transistor, for example.

### BACKGROUND ART

Thin film transistors (hereinafter, “TFT”) are used as switching elements on an active matrix substrate, for example. In the present specification, such TFTs will be referred to as “pixel TFTs”. As pixel TFTs, amorphous silicon TFTs whose active layer is an amorphous silicon film (hereinafter abbreviated as an “a-Si film”), crystalline silicon TFTs whose active layer is a crystalline silicon film (hereinafter abbreviated as a “c-Si film”), and the like have been widely used. Generally speaking, a c-Si film has a higher field-effect mobility than that of an a-Si film, and therefore a crystalline silicon TFT has a higher current driving power (i.e., a larger ON current) than that of an amorphous silicon TFT.

In an active matrix substrate for use in a display apparatus or the like, a c-Si film to become the active layers of crystalline silicon TFTs may be formed by, after forming an a-Si film on a glass substrate, irradiating the a-Si film with laser light so as to crystallize it, for example.

As a crystallization method based on laser annealing, a method has been proposed which employs a microlens array to converge laser light exclusively on regions of an a-Si film to become active layers of TFTs, thus to locally crystallize the a-Si film (Patent Documents 1, 2 and 3). In the present specification, this crystallization method will be referred to as a “local laser annealing technique”. By using a local laser annealing technique, as compared to any conventional laser annealing technique that scans the entire surface of an a-Si film with linear-shaped laser light (which may be referred to as an excimer laser annealing technique: ELA technique), the time required for crystallization can be considerably reduced, whereby mass producibility can be enhanced. Moreover, Patent Document 4 discloses a laser irradiation device suitable for use in the local laser annealing technique. The entire disclosure of Patent Documents 1 to 3 is incorporated herein by reference.

### CITATION LIST

### Patent Literature

[Patent Document 1] Japanese Laid-Open Patent Publication No. 2011-29411

[Patent Document 2] International Publication No. 2011/132559

[Patent Document 3] International Publication No. 2017/145519

[Patent Document 4] Japanese Laid-Open Patent Publication No. 2017-38073

### SUMMARY OF INVENTION

### Technical Problem

However, even by using the apparatus described in Patent Document 4, ridges may form at e.g. grain boundaries of the p-Si film to be formed through crystallization, thereby lowering the characteristics and reliability of the TFT.

Studies by the inventors have found this to be due to a failure to adequately reduce or remove oxygen (molecules or ions) existing in the neighborhood of the a-Si film.

The present invention has been made in view of the above circumstances, and an objective thereof is to provide a laser annealing method that can form a p-Si film in which ridge formation is suppressed, and a laser annealing apparatus suitable for use in performing such a laser annealing method.

### Solution to Problem

A laser annealing method according to an embodiment of the present invention comprises: step A of disposing a substrate on a stage, the substrate having an amorphous silicon film formed on a surface thereof; step B of supplying a first nitrogen gas at −100° C. or below toward a surface in a selected region of the amorphous silicon film; and step C of emitting a plurality of laser beams toward the selected region having the first nitrogen gas supplied thereto, to form a plurality of crystalline silicon islets in the amorphous silicon film.

A laser annealing apparatus according to an embodiment of the present invention comprises: a stage to receive a substrate, the substrate having an amorphous silicon film formed on a surface thereof; a first nitrogen gas supplying device to supply a first nitrogen gas at −100° C. or below toward a selected region of a surface of the amorphous silicon film; and a laser irradiation device to emit a plurality of laser beams into the selected region of the surface of the amorphous silicon film, wherein the first nitrogen gas supplying device and the laser irradiation device are capable of making a relative movement with respect to the substrate on the stage, and the first nitrogen gas supplying device is disposed upstream of the laser irradiation device regarding a direction of the relative movement of the substrate.

A method of producing an active matrix substrate according to an embodiment of the present invention comprises: a step of forming a plurality of crystalline silicon islets by the laser annealing method of any of the above; and a step of forming a plurality of TFTs by using the plurality of crystalline silicon islets.

### Advantageous Effects of Invention

According to an embodiment of the present invention, there is provided a laser annealing method that can form a p-Si film in which ridge formation is suppressed. According to another embodiment of the present invention, a laser annealing apparatus suitable for use in performing such a laser annealing method is provided.

### BRIEF DESCRIPTION OF DRAWINGS

FIG. 1 A schematic diagram of a laser annealing apparatus 100 according to an embodiment of the present invention.

FIG. 2 A schematic diagram of a laser annealing apparatus 200 according to another embodiment of the present invention.

FIG. 3 A schematic diagram of a laser annealing apparatus 300 according to still another embodiment of the present invention.

FIG. 4 A schematic diagram of a laser annealing apparatus 400 according to still another embodiment of the present invention.

FIG. 5 A schematic diagram showing an example where a baffle 62 is provided in the laser annealing apparatus 100.

FIG. 6 A schematic diagram of a laser irradiation device 10 included in the laser annealing apparatuses 100 to 400.

FIG. 7 A schematic diagram showing a mask 32 and a microlens array 34 included in the laser irradiation device 10.

### DESCRIPTION OF EMBODIMENTS

Hereinafter, with reference to the drawings, laser annealing apparatuses and laser annealing methods according to embodiments of the present invention will be described. The laser annealing apparatuses and laser annealing methods illustrated below are suitable for use in the manufacture of a TFT substrate of a liquid crystal display panel, for example.

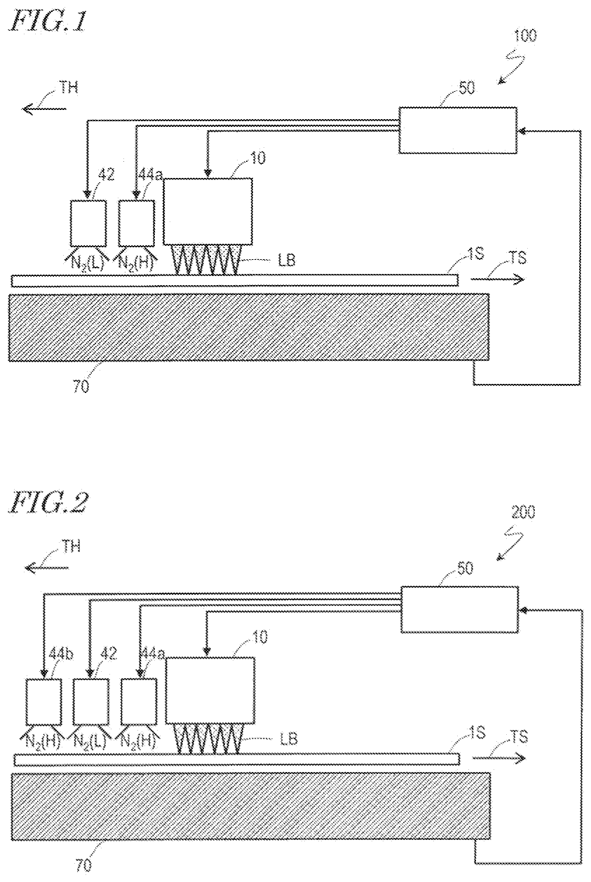

A laser annealing apparatus 100 shown in FIG. 1 includes a laser irradiation device 10, a first nitrogen gas supplying device 42, a stage 70, and a control device 50 for controlling these.

The stage 70 receives a substrate 1S, the substrate 1S having an amorphous silicon film formed on a surface thereof, and is able to move the substrate 1S in the direction of arrow TS in FIG. 1. The substrate 1S is a glass substrate, for example. It may be the stage 70 itself or the upper face of the stage 70 that moves; alternatively, only the substrate 1S on the stage 70 may be caused to move. For example, the stage 70 may have a structure for releasing a dry nitrogen gas from its upper face toward the bottom face of the substrate 1S, and may be configured so that the substrate 1S is moved in the direction of arrow TS while the substrate 1S is lifted off the upper face of the stage 70. Note that the amorphous silicon film can be formed on by a known method (e.g., the CVD technique) on the glass

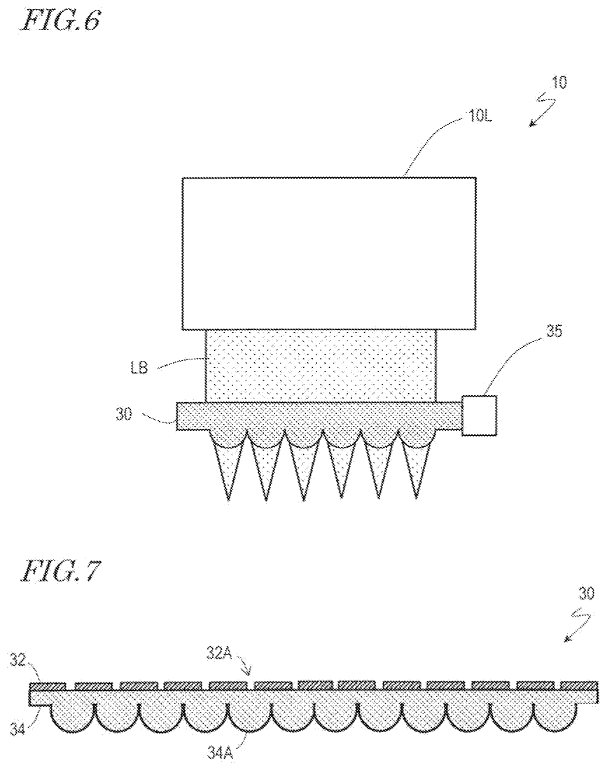

The laser irradiation device 10 emits a laser beam LB, e.g. of an ultraviolet range, toward the amorphous silicon film on the surface of the substrate 1S. As the laser beam, green laser (a second harmonic of YAG laser) or blue laser may be used. As schematically shown in FIG. 6, the laser irradiation device 10 includes a laser light source 10L and a microlens unit 30.

As shown in FIG. 7, the microlens unit 30 includes: a microlens array 34 having a plurality of microlenses 34A; and a mask 32 disposed between the laser light source 10L and the plurality of microlenses 34A. The mask 32 has a plurality of apertures 32A, the plurality of apertures 32A being disposed correspondingly to the respective microlenses 34A. The laser beam LB having passed through the apertures 32A is converged by the microlenses 34A, and is radiated onto a predetermined region of the amorphous silicon film, i.e., the region where an active layer of the TFT is to be formed. The microlens unit 30 has its relative position regarding the substrate 1S adjusted by an alignment adjustment device 35, for example.

The laser light source 10L includes a plurality of solid laser elements, for example. As the solid laser elements, YAG laser elements (second harmonic: wavelength 532 nm) can be used, for example. Note that excimer lasers, such as XeCl excimer lasers (wavelength 308 nm), may also be used. As necessary, the laser irradiation device 10 may further include optical elements such as a beam expander, a collimator, and a reflecting mirror.

Toward a selected region of the surface of the amorphous silicon film, the first nitrogen gas supplying device 42 supplies a nitrogen gas at −100° C. or below (hereinafter referred to as a “low-temperature nitrogen gas”). The low-temperature nitrogen gas is supplied through tubing from a Dewar condenser of liquid nitrogen, for example. In the case where some tubing for liquid nitrogen is installed within the factory, such tubing may be utilized. The first nitrogen gas supplying device 42 includes e.g. a mass flow controller (MFC), and supplies a cold nitrogen gas at a predetermined flow rate to the selected region of the surface of the amorphous silicon film. The temperature of the low-temperature nitrogen gas is −100° C. or below, and preferably −130° C. or below, but not below −196° C. (77 K).

Together with the laser irradiation device 10, the first nitrogen gas supplying device 42 is capable of making a relative movement with respect to the substrate 1S on the stage 70, in the direction of arrow TH in FIG. 1, and the first nitrogen gas supplying device 42 is disposed upstream of the laser irradiation device 10. In other words, after the nitrogen gas is supplied by the first nitrogen gas supplying device 42, the laser beam LB is radiated by the laser irradiation device 10. Note that, as described above, the substrate 1S may be moved in the direction of arrow TS, or the first nitrogen gas supplying device 42 and the laser irradiation device 10 may be moved in the direction of arrow TH.

Once the low-temperature nitrogen gas is supplied onto the surface of the amorphous silicon film, the temperature of the surface of the amorphous silicon film decreases, thereby making it easier for the nitrogen gas (nitrogen molecules) to be adsorbed to the surface (physical adsorption). Therefore, by supplying a nitrogen gas (a large amount of nitrogen molecules) at −100° C. or below, physical adsorption of the nitrogen gas (nitrogen molecules) is promoted, and the oxygen molecules and/or oxygen ions existing near the surface of the amorphous silicon film can be eliminated. This can restrain or prevent ridges from being formed when the amorphous silicon is melted and crystallized.

The low-temperature nitrogen gas is preferably supplied at a pressure of e.g. not less than about 500 kPa but less than about 5000 kPa. Herein, the distance from a nitrogen gas outlet (nozzle) of the first nitrogen gas supplying device 42 to the amorphous silicon film on the substrate 1S is preferably less than 300 mm, and more preferably 100 mm or less. The distance between the laser irradiation device 10 and the substrate 1S is also preferably less than 300 mm. The flow rate of the nitrogen gas, the distance to the substrate 1S, and the like may be appropriately set so that the nitrogen gas to be supplied from the first nitrogen gas supplying device 42 onto the substrate 1S will encompass the region to be irradiated with the laser beam LB. Although depending on the area of the region to be irradiated with laser and the speed of stepping, the flow rate of the low-temperature nitrogen gas is approximately not less than 300 L/min and not more than 3000 L/min, for example.

The nitrogen gas to be supplied to the first nitrogen gas supplying device 42 preferably has a purity of 99.99% or more, and more preferably has 99.9999% or more.

Between the first nitrogen gas supplying device 42 and the laser irradiation device 40, the laser annealing apparatus 100 shown in FIG. 1 further includes a second nitrogen gas supplying device 44a, which is optional. The second nitrogen gas supplying device 44a supplies a second nitrogen gas at ambient temperature or above toward the selected region of the amorphous silicon film. The ambient temperature may be e.g. room temperature, whereas the ambient pressure may be atmospheric pressure. The second nitrogen gas supplying device 44a is capable of moving together with the first nitrogen gas supplying device 42, and is controlled by the control device 50.

Prior to laser beam irradiation, the second nitrogen gas supplying device 44a supplies a second nitrogen gas (hereinafter referred to as a “high-temperature nitrogen gas”) at ambient temperature or above to the region to which the low-temperature nitrogen gas has been supplied by the first nitrogen gas supplying device 42. The high-temperature nitrogen gas is supplied in order to prevent condensation on the optical system (e.g., microlenses, masks) of the laser irradiation device 10 due to the low-temperature nitrogen gas, and/or to prevent minute pieces of ice or droplets of water from drifting in the optical path of the laser beam LB (i.e., the space between the laser irradiation device 10 and the amorphous silicon film on the substrate 1S).

The pressure at which to supply the low-temperature nitrogen gas is higher than the pressure at which to supply the high-temperature nitrogen gas. In other words, the pressure at which to supply the high-temperature nitrogen gas is smaller than the pressure at which to supply the low-temperature nitrogen gas. Oxygen near the surface of the amorphous silicon film has been removed with the supply of the low-temperature nitrogen gas, and the high-temperature nitrogen gas only needs to prevent condensation or the like as stated above. If the pressure of the high-temperature nitrogen gas supplied from the second nitrogen gas supplying device 44a is too high, it may hinder the low-temperature nitrogen gas supplied from the first nitrogen gas supplying device 42 from reaching the surface of the amorphous silicon film. Preferably, the pressure at which to supply the high-temperature nitrogen gas is e.g. 100 kPa to 4000 kPa, and does not exceed the pressure at which to supply the low-temperature nitrogen gas. Preferably, the flow rate of the high-temperature nitrogen gas is e.g. approximately not less than 60 L/min and not more than 2400 L/min, and does not exceed the flow rate of the low-temperature nitrogen gas.

Moreover, the distance from the second nitrogen gas supplying device 44a to the amorphous silicon film on the substrate 1S may be greater than the distance from the first nitrogen gas supplying device 42 to the amorphous silicon film on the substrate 1S. As in the case of the low-temperature nitrogen gas, it is also preferable for the high-temperature nitrogen gas to have a purity of 99.99% or more, and more preferable that of 99.9999% or more. The high-temperature nitrogen gas may be supplied via a nitrogen gas cylinder, a nitrogen gas generation apparatus, or nitrogen gas tubing within the factory. It will be appreciated that dust removal or purification may be applied as necessary, by using a filter or the like.

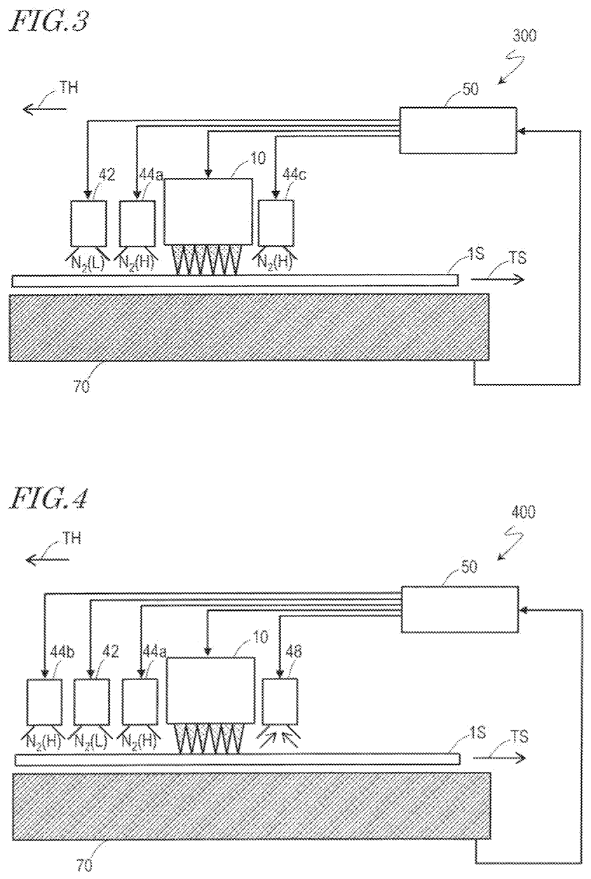

A laser annealing apparatus 200 shown in FIG. 2 differs from the laser annealing apparatus 100 in that it further includes a third nitrogen gas supplying device 44b which is disposed upstream of the first nitrogen gas supplying device 42 and which is capable of moving together with the first nitrogen gas supplying device 42. In the laser annealing apparatus 200, as in the case of the laser annealing apparatus 100, the second nitrogen gas supplying device 44a may be omitted.

To the selected region of the amorphous silicon film to which the low-temperature nitrogen gas is to be supplied by the first nitrogen gas supplying device 42, the third nitrogen gas supplying device 44b supplies the high-temperature nitrogen gas prior to that. This allows oxygen molecules and/or oxygen ions to be eliminated from the region of the amorphous silicon film irradiated with the laser beam LB more effectively. As in the case of the second nitrogen gas supplying device 44a, a nitrogen gas having a purity of 99.99% or more is supplied to the third nitrogen gas supplying device 44b through tubing, for example.

The pressure of the high-temperature nitrogen gas supplied from the third nitrogen gas supplying device 44b may be higher than, lower than, or equal to the pressure of the low-temperature nitrogen gas supplied from the first nitrogen gas supplying device 42. However, if the pressure of the high-temperature nitrogen gas supplied from the third nitrogen gas supplying device 44b is too high, it may hinder the low-temperature nitrogen gas supplied from the first nitrogen gas supplying device 42 from reaching the surface of the amorphous silicon film; therefore, it preferably does not exceed the pressure of the low-temperature nitrogen gas supplied from the first nitrogen gas supplying device 42.

A laser annealing apparatus 300 shown in FIG. 3 differs from the laser annealing apparatus 100 in that it further includes a fourth nitrogen gas supplying device 44c which is disposed downstream of the laser irradiation device 10 and which is capable of moving together with the first nitrogen gas supplying device 42. In the laser annealing apparatus 300, too, the second nitrogen gas supplying device 44a may be omitted, as in the case of the laser annealing apparatus 100.

As does the second nitrogen gas supplying device 44a, the fourth nitrogen gas supplying device 44c supplies a high-temperature nitrogen gas. The high-temperature nitrogen gas prevents condensation on the optical system of the laser irradiation device 10 due to the low-temperature nitrogen gas, and/or prevents minute pieces of ice or droplets of water from drifting in the optical path of the laser beam LB. The pressure of the high-temperature nitrogen gas supplied from the fourth nitrogen gas supplying device 44c may be higher than, lower than, or equal to the pressure at which to supply the low-temperature nitrogen gas.

In the laser annealing apparatus 300, a third nitrogen gas supplying device 44b may be provided upstream of the first nitrogen gas supplying device 42, as in the laser annealing apparatus 200.

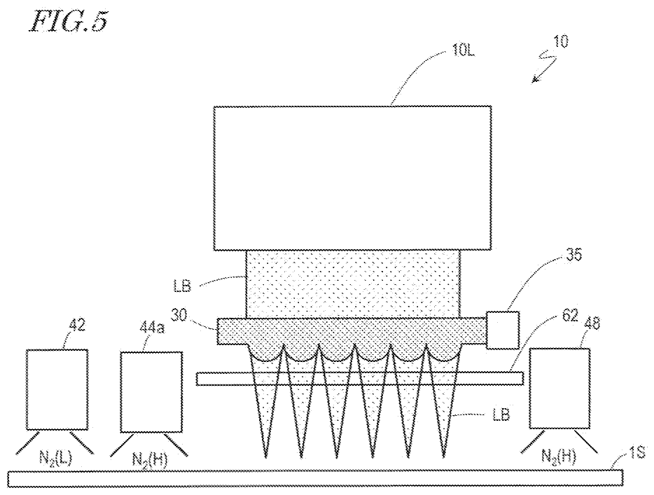

A laser annealing apparatus 400 shown in FIG. 4 further includes, downstream of the laser irradiation device 10 in the laser annealing apparatus 200 shown in FIG. 2, a gas suction device 48 which is capable of moving together with the first nitrogen gas supplying device 42. The gas suction device 48 sucks in the ambient gas above the amorphous silicon film.

In the laser annealing apparatus 400, a portion of the high-temperature nitrogen gas supplied from the second nitrogen gas supplying device 44a is sucked by the gas suction device 48. In other words, a flow of high-temperature nitrogen gas is created in the region which is irradiated by the laser irradiation device 10 with the laser beam LB. Therefore, the high-temperature nitrogen gas supplied from the second nitrogen gas supplying device 44a is effectively led under the laser irradiation device 10, thereby effectively preventing condensation, etc., on the optical system of the laser irradiation device 10.

In the laser annealing apparatus 400, the third nitrogen gas supplying device 44b may be omitted.

Next, FIG. 5 is referred to

FIG. 5 is a schematic diagram showing an example where a baffle 62 is provided in the laser annealing apparatus 300. The baffle 62 may similarly be provided in the other laser annealing apparatuses 100, 200 and 400.

As shown in FIG. 5, the baffle 62 may be provided under an outgoing surface of the laser irradiation device 10. The baffle 62 is preferably larger than the outgoing surface (e.g., the microlens unit 30) of the laser irradiation device 10, and restrains the low-temperature nitrogen gas supplied from the first nitrogen gas supplying device 42 from reaching the optical system of the laser irradiation device 10. In other words, the baffle 62 can restrict the low-temperature nitrogen gas flow, and protect the optical system (including the outgoing surface) of the laser irradiation device 10.

Note that the optical system (e.g., the microlens array of the laser irradiation device 10) being subject to the laser beam LB may therefore become heated. In such a case, the baffle 62 may be omitted. Conversely, in order to better prevent condensation on the optical system of the laser irradiation device 10, the baffle 62 may be allowed to be heated. For example, a resistive heating element may be provided on a glass plate. For example, an ITO (indium tin oxide) layer or thin lines of metal may be provided.

As described above, a plurality of TFTs are formed by using an amorphous silicon film on which a plurality of crystalline silicon islets are formed. The active matrix substrate on which the TFTs have been formed is suitable for use in a liquid crystal display apparatus or an organic EL display apparatus.

### INDUSTRIAL APPLICABILITY

A laser annealing method and laser annealing apparatus according to an embodiment of the present invention are suitable for use in the manufacture of a semiconductor device including thin film transistors. In particular, they are suitable for use in the manufacture of a liquid crystal display apparatus and an organic EL display apparatus having a large area.

### REFERENCE SIGNS LIST

1S: substrate (glass substrate)
10: laser irradiation device
10L: laser light source
30: microlens unit
32: mask
32A: aperture
34: microlens array
34A: microlens
35: alignment adjustment device
42: tow-temperature nitrogen gas supplying device (first nitrogen gas supplying device)
44a, 44b, 44c: high-temperature nitrogen gas supplying device (second to fourth nitrogen gas supplying devices)
48: gas suction device
50: control device
62: baffle (gas-flow restricting plate, protection plate)
70: stage
100, 200, 300, 400: laser annealing apparatus
LB: laser beam

1. A laser annealing method comprising:
step A of disposing a substrate on a stage, the substrate having an amorphous silicon film formed on a surface thereof;
step B of supplying a first nitrogen gas at −100° C. or below toward a surface in a selected region of the amorphous silicon film; and
step C of emitting a plurality of laser beams toward the selected region having the first nitrogen gas supplied thereto, to form a plurality of crystalline silicon islets in the amorphous silicon film.

2. The laser annealing method of claim 1 further comprising, after the aforementioned step B and before the aforementioned step C, step D1 of supplying a second nitrogen gas at ambient temperature or above toward the selected region.

3. The laser annealing method of claim 2, wherein a pressure at which the first nitrogen gas is supplied in the aforementioned step B is higher than a pressure at which the second nitrogen gas is supplied in the aforementioned step D1.

4. The laser annealing method of claim 1, further comprising, before the aforementioned step B, step D2 of supplying a third nitrogen gas at ambient temperature or above toward the selected region.

5. The laser annealing method of claim 1, further comprising step E of, while performing the aforementioned step C, supplying a fourth nitrogen gas at ambient temperature or above toward a region downstream of the selected region.

6. The laser annealing method of claim 2, further comprising a step of, while performing the aforementioned step C, sucking an ambient gas above a region downstream of the selected region.

7. A laser annealing apparatus comprising:
a stage to receive a substrate, the substrate having an amorphous silicon film formed on a surface thereof;
a first nitrogen gas supplying device to supply a first nitrogen gas at −100° C. or below toward a selected region of a surface of the amorphous silicon film; and
a laser irradiation device to emit a plurality of laser beams into the selected region of the surface of the amorphous silicon film, wherein the first nitrogen gas supplying device and the laser irradiation device are capable of making a relative movement with respect to the substrate on the stage, and the first nitrogen gas supplying device is disposed upstream of the laser irradiation device regarding a direction of the relative movement of the substrate.

8. The laser annealing apparatus of claim 7, further comprising a second nitrogen gas supplying device to supply a second nitrogen gas at ambient temperature or above toward the selected region of the amorphous silicon film, the second nitrogen gas supplying device being disposed between the first nitrogen gas supplying device and the laser irradiation device and being capable of moving together with the first nitrogen gas supplying device.

9. The laser annealing apparatus of claim 7, further comprising a third nitrogen gas supplying device to supply a third nitrogen gas at ambient temperature or above toward the selected region of the amorphous silicon film, the third nitrogen gas supplying device being disposed upstream of the first nitrogen gas supplying device and being capable of moving together with the first nitrogen gas supplying device.

10. The laser annealing apparatus of claim 7, further comprising a fourth nitrogen gas supplying device to supply a fourth nitrogen gas at ambient temperature or above toward the selected region of the amorphous silicon film, the fourth nitrogen gas supplying device being disposed downstream of the laser irradiation device and being capable of moving together with the first nitrogen gas supplying device.

11. The laser annealing apparatus of claim 8, further comprising a gas suction device to suck an ambient gas above the amorphous silicon film, the gas suction device being disposed downstream of the laser irradiation device and being capable of moving together with the first nitrogen gas supplying device.

12. The laser annealing apparatus of claim 7, further comprising a baffle disposed below an outgoing surface of the laser irradiation device.

13. The laser annealing apparatus of claim 7, wherein the laser irradiation device further includes: a plurality of solid laser elements; a plurality of microlenses; and a mask disposed between the plurality of solid laser elements and the plurality of microlenses.

14. A method of producing an active matrix substrate, comprising:
a step of forming a plurality of crystalline silicon islets by the laser annealing method of claim 1; and
a step of forming a plurality of TFTs by using the plurality of crystalline silicon islets.
